(19) United States
(12) Patent Application Publication
(10) Pub. No.: US 2024/0324218 A1
(43) Pub. Date: Sep. 26, 2024

(54) NON-VOLATILE MEMORY DEVICE AND ELECTRONIC SYSTEM INCLUDING THE SAME

(71) Applicant: Samsung Electronics Co., Ltd., Suwon-si (KR)

(72) Inventors: Jehong OH, Suwon-si (KR); Younghwan JO, Suwon-si (KR); Seulye KIM, Suwon-si (KR); Moohyun KIM, Suwon-si (KR); Sunggil KIM, Suwon-si (KR)

(73) Assignee: Samsung Electronics Co., Ltd., Suwon-si (KR)

(21) Appl. No.: 18/601,245

(22) Filed: Mar. 11, 2024

(30) Foreign Application Priority Data
Mar. 24, 2023 (KR) 10-2023-0038970
May 17, 2023 (KR) 10-2023-0063805

(51) Int. Cl. H10B 43/27; H10B 41/27; H10B 41/35; H10B 41/41; H10B 43/35; H10B 43/40

(52) U.S. Cl. CPC H10B 43/27; H10B 41/27; H10B 41/35; H10B 41/41; H10B 43/35; H10B 43/40

(57) ABSTRACT

A non-volatile memory device includes a substrate including a memory cell region and a connection region, a mold structure including a plurality of gate electrodes sequentially stacked on the memory cell region and stacked stepwise on the connection region, and a plurality of mold insulating layers alternately stacked with the plurality of gate electrodes, a channel hole vertically passing through the mold structure on the memory cell region, and a channel structure disposed in the channel hole, wherein the channel structure includes a gate insulating layer, a channel layer, and a buried insulating layer sequentially disposed in the channel hole, and the channel layer includes a grain having a size of about 20 nm to about 17 μm.

### CROSS-REFERENCE TO RELATED APPLICATION

This application is based on and claims priority under 35 U.S.C. §119 to Korean Patent Application Nos. 10-2023-0038970, filed on Mar. 24, 2023, and 10-2023-0063805, filed on May 17, 2023, in the Korean Intellectual Property Office, the disclosures of which are incorporated by reference herein in their entireties.

### TECHNICAL FIELD

The inventive concept relates generally to a non-volatile memory device and an electronic system including the same, and more specifically to a non-volatile memory device having a vertical channel and an electronic system including the same.

### BACKGROUND

In general, it is desirable to increase the degree of integration of conventional non-volatile memory devices to meet the high performance and low price required by consumers. In the case of a non-volatile memory device, because the degree of integration is an important factor in determining the price of a product, an increased degree of integration is particularly desirable.

In the case of a two-dimensional or planar non-volatile memory device, because the degree of integration is mainly determined by an area occupied by a unit memory cell, the degree of integration is greatly affected by the level of technology of forming a fine pattern. However, because ultra-expensive equipment is required for miniaturization of a pattern, although the degree of integration of the two-dimensional non-volatile memory device is increasing, the increase in degree of integration is still limited. Accordingly, 3D non-volatile memory devices including memory cells arranged three-dimensionally have been proposed.

### SUMMARY

Various embodiments provide a non-volatile memory device with improved performance and reliability.

Some embodiments provide an electronic system with improved performance and reliability. The technical problems solved by one or more embodiments disclosed herein are not limited to the problems mentioned above, and other problems not mentioned will be clearly understood by those skilled in the art from the description below.

According to various embodiments, there is provided a non-volatile memory device. The non-volatile memory device includes: a substrate including a memory cell region and a connection region; a mold structure including a plurality of gate electrodes sequentially stacked on the memory cell region and stacked stepwise on the connection region, and a plurality of mold insulating layers alternately stacked with the plurality of gate electrodes; a channel hole vertically passing through the mold structure on the memory cell region; and a channel structure disposed in the channel hole, wherein the channel structure includes a gate insulating layer, a channel layer, and a buried insulating layer sequentially disposed in the channel hole, and the channel layer includes a grain having a size of about 20 nm to about 17 μm.

In some embodiments the non-volatile memory device includes: a peripheral circuit structure and a cell array structure sequentially stacked on a substrate, wherein the cell array structure includes: a mold structure including a plurality of gate electrodes sequentially stacked on a memory cell region of the substrate and stacked stepwise on a connection region of the substrate, and a plurality of mold insulating layers alternately stacked with the plurality of gate electrodes; and a channel layer vertically passing through the mold structure on the memory cell region and intersecting with the plurality of gate electrodes, wherein the channel layer includes a grain having a size of about 20 nm to about 17 μm.

According to some embodiments, there is provided an electronic system. The electronic system includes: a main board; a non-volatile memory device on the main board; and a controller electrically connected to the non-volatile memory device on the main board, wherein the non-volatile memory device includes: a substrate including a memory cell region and a connection region; a mold structure including a plurality of gate electrodes sequentially stacked on the memory cell region and stacked stepwise on the connection region, and a plurality of mold insulating layers alternately stacked with the plurality of gate electrodes; a source layer disposed between the substrate and the mold structure; a channel hole vertically passing through the mold structure on the memory cell region; and a channel structure disposed in the channel hole, wherein the channel structure includes a gate insulating layer, a silicon channel layer, and a buried insulating layer sequentially disposed in the channel hole, the silicon channel layer is apart from the substrate with the source layer therebetween, and the silicon channel layer includes a silicon grain having a size of about 20 nm to about 17 μm.

### BRIEF DESCRIPTION OF THE DRAWINGS

Embodiments will be more clearly understood from the following detailed description taken in conjunction with the accompanying drawings in which:

FIG. 1 is a block diagram of a non-volatile memory device according to embodiments;

FIG. 2 is an equivalent circuit diagram of a memory cell array of a non-volatile memory device according to embodiments;

FIG. 3 is a perspective view illustrating a representative configuration of a non-volatile memory device according to embodiments;

FIG. 4 is a plan view of the non-volatile memory device of FIG. 3;

FIG. 5 is a cross-sectional view taken along line A-A′ of FIG. 4;

FIG. 6 is a cross-sectional view taken along line B-B′ of FIG. 4:

FIG. 7 is an enlarged view of an area EX1 of FIG. 6;

FIG. 8 illustrates a non-volatile memory device according to embodiments, and is a cross-sectional view corresponding to a cross-section taken along line B-B′ of FIG. 4:

FIGS. 9 to 19 are cross-sectional views illustrating a method of manufacturing a non-volatile memory device, according to embodiments;

FIG. 20 is a schematic diagram illustrating a data storage system including a non-volatile memory device according to embodiments;

FIG. 21 is a schematic perspective view illustrating a data storage system including a non-volatile memory device according to embodiments; and

FIG. 22 is a schematic cross-sectional view illustrating semiconductor packages according to embodiments.

### DETAILED DESCRIPTION OF THE EMBODIMENTS

Hereinafter, various embodiments will be described in detail with reference to the accompanying drawings.

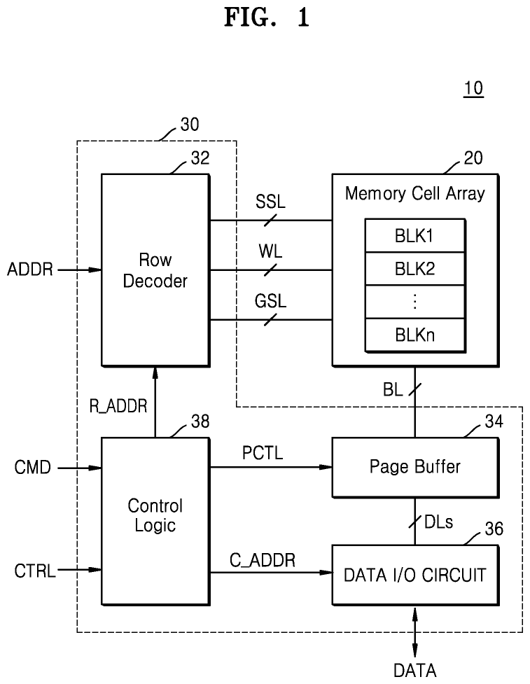

FIG. 1 is a block diagram of a non-volatile memory device 10 according to embodiments.

Referring to FIG. 1, the non-volatile memory device 10 may include a memory cell array 20 and a peripheral circuit 30. The memory cell array 20 includes a plurality of memory cell blocks BLK1, BLK2 . . . BLKn. Each of the plurality of memory cell blocks BLK1, BLK2 . . . BLKn may include a plurality of memory cells. The plurality of memory cell blocks BLK1, BLK2 . . . BLKn may be connected to the peripheral circuit 30 through a bit line BL, a word line WL, a string select line SSL, and a ground select line GSL.

The peripheral circuit 30 may include a row decoder 32, a page buffer 34, a data input/output circuit 36, and a control logic 38. Although not shown in FIG. 1, the peripheral circuit 30 may further include an input/output interface, a column logic, a voltage generator, a pre-decoder, a temperature sensor, a command decoder, an address decoder, an amplifier circuit, and the like.

The memory cell array 20 may be connected to the page buffer 34 through a bit line BL and may be connected to the row decoder 32 through the word line WL, the string select line SSL, and the ground select line GSL. In the memory cell array 20, each of the plurality of memory cells included in the plurality of memory cell blocks BLK1, BLK2 . . . BLKn may be a flash memory cell. The memory cell array 20 may include a 3D memory cell array. The 3D memory cell array may include a plurality of NAND strings, and each of the plurality of NAND strings may include a plurality of memory cells connected to a plurality of word lines WL vertically stacked on a substrate.

The peripheral circuit 30 may receive an address ADDR, a command CMD, and a control signal CTRL from the outside of the non-volatile memory device 10 and may transmit/receive data to/from a device outside the non-volatile memory device 10.

The row decoder 32 may select at least one of the plurality of memory cell blocks BLK1, BLK2 . . . BLKn in response to an external address ADDR and may select a word line WL, a string select line SSL, and a ground select line GSL of the selected memory cell block. The row decoder 32 may transmit a voltage for performing a memory operation to the word line WL of the selected memory cell block.

The page buffer 34 may be connected to the memory cell array 20 through a bit line BL. The page buffer 34 operates as a write driver during a program operation to apply a voltage according to data to be stored in the memory cell array 20 to the bit line BL, and may detect data stored in the memory cell array 20 by operating as a sense amplifier during a read operation. The page buffer 34 may operate according to a control signal PCTL provided from the control logic 38.

The data input/output circuit 36 may be connected to the page buffer 34 through data lines DLs. The data input/output circuit 36 may receive data from a memory controller (not shown) during a program operation and may provide program data to the page buffer 34 based on a column address C_ADDR provided from the control logic 38. During a read operation, the data input/output circuit 36 may provide the read data stored in the page buffer 34 to the memory controller based on the column address C_ADDR provided from the control logic 38.

The data input/output circuit 36 may transfer an input address or a command to the control logic 38 or the row decoder 32. The peripheral circuit 30 may further include an Electro Static Discharge (ESD) circuit and a pull-up/pull-down driver.

The control logic 38 may receive a command CMD and a control signal CTRL from the memory controller. The control logic 38 may provide a row address R_ADDR to the row decoder 32 and the column address C_ADDR to the data input/output circuit 36. The control logic 38 may generate various internal control signals used in the non-volatile memory device 10 in response to the control signal CTRL. For example, the control logic 38 may adjust a voltage level provided to the word line WL and the bit line BL when a memory operation, such as a program operation or an erase operation is performed.

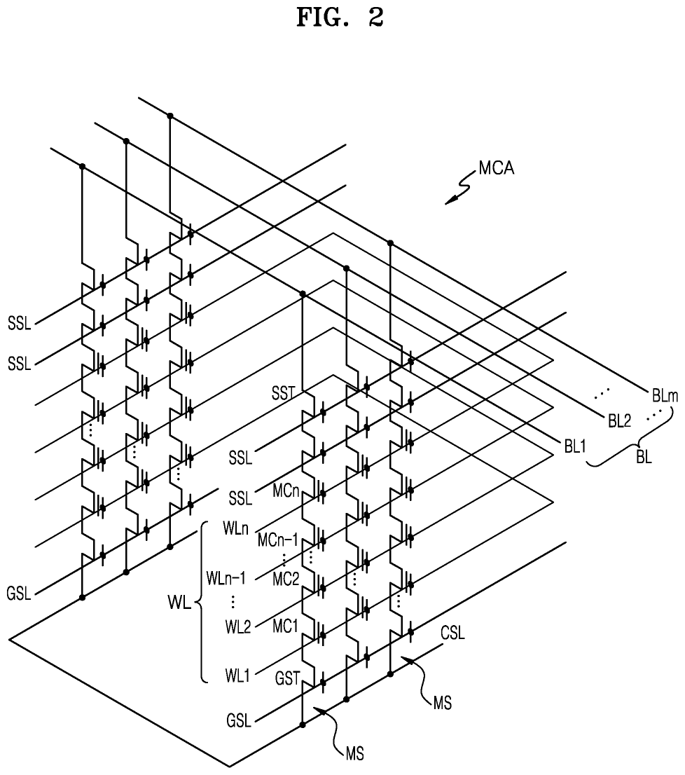

FIG. 2 is an equivalent circuit diagram of a memory cell array MCA of a non-volatile memory device 10 according to embodiments.

Referring to FIG. 2, the memory cell array MCA may include a plurality of memory cell strings MS. The memory cell array MCA may include a plurality of bit lines BL (BL1, BL2 . . . BLm), a plurality of word lines WL (WL1, WL2 . . . WLn-1, WLn), at least one string select line SSL, at least one ground select line GSL, and a common source line CSL. A plurality of memory cell strings MS may be formed between the plurality of bit lines BL (BL1, BL2 . . . BLm) and the common source line CSL. In FIG. 2. although a case is illustrated that each of the plurality of memory cell strings MS includes two string select lines SSL, the technical aspects of the various embodiments are not limited thereto. For example, each of the plurality of memory cell strings MS may include one string select line SSL.

Each of the plurality of memory cell strings MS may include a string select transistor SST, a ground select transistor GST, and a plurality of memory cell transistors MC1, MC2 . . . MCn-1, MCn. A drain region of the string select transistor SST may be connected to bit lines BL (BL1, BL2 . . . BLm), and a source region of the ground select transistor GST may be connected to the common source line CSL. The common source line CSL may be a region where source regions of the plurality of ground select transistors GST are connected in common.

The string select transistor SST may be connected to the string select line SSL, and the ground select transistor GST may be connected to the ground select line GSL. The plurality of memory cell transistors MC1, MC2 . . . MCn-1, MCn may be connected to the plurality of word lines WL (WL1. WL2 . . . WLn-1, WLn), respectively.

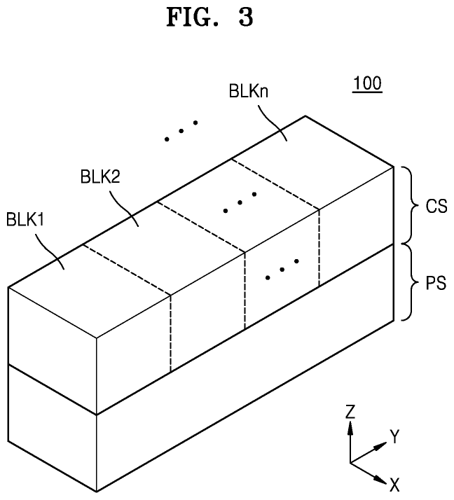

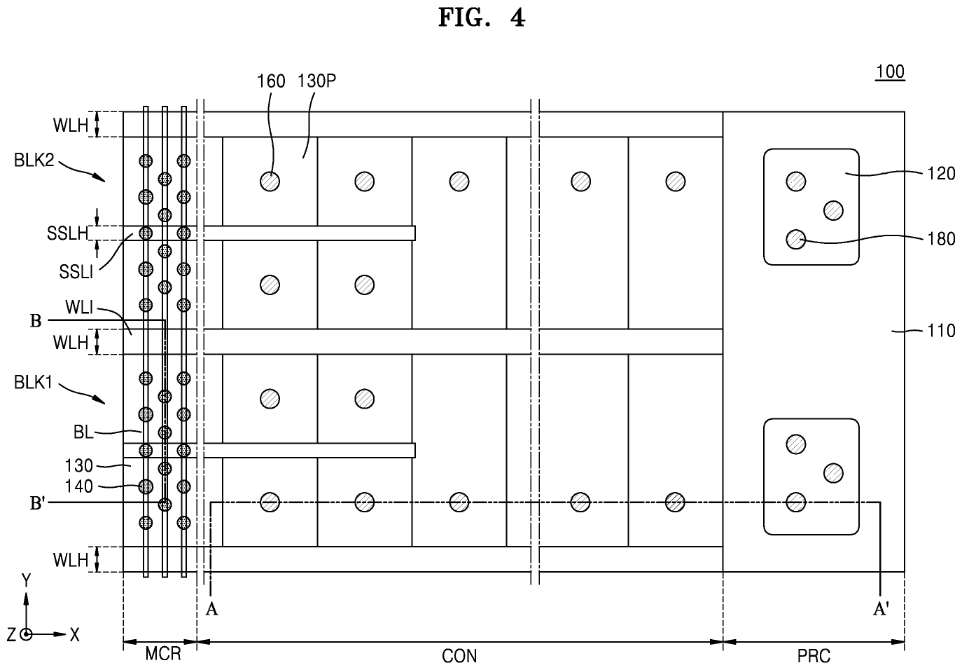

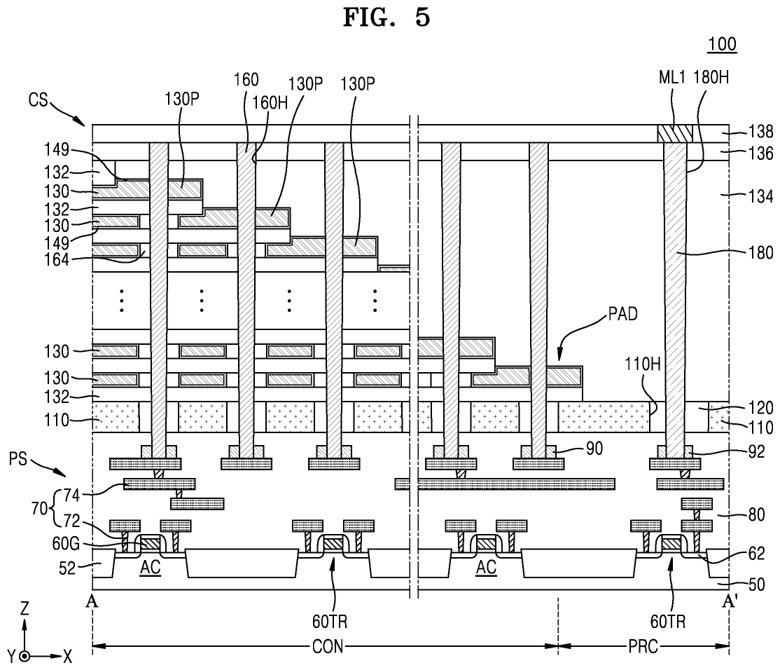

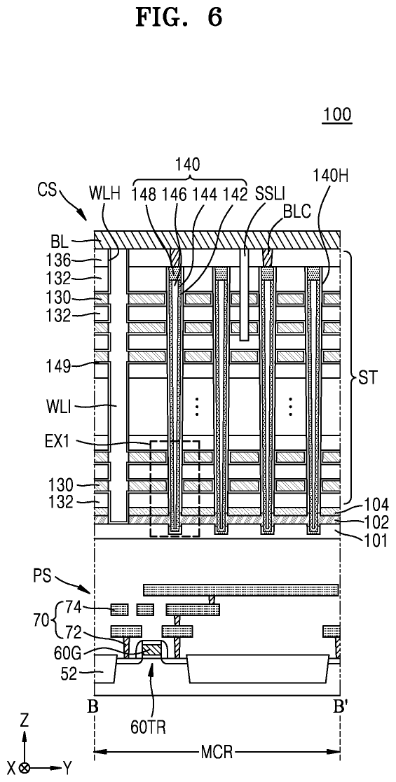

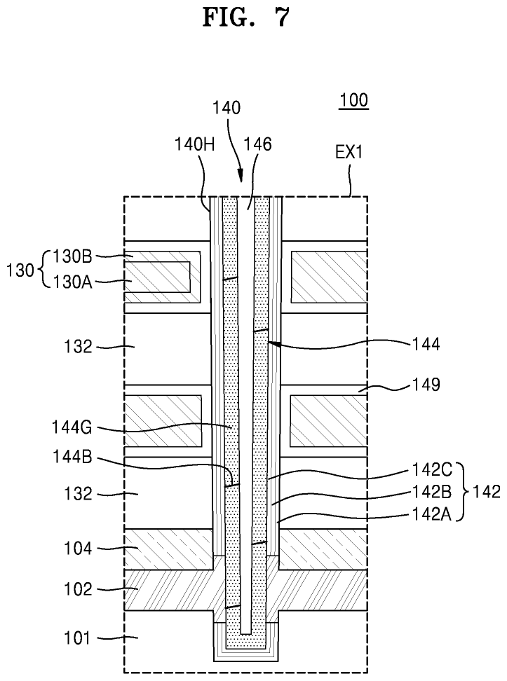

FIGS. 3 to 7 are diagrams for explaining a non-volatile memory device 100 according to embodiments. Specifically, FIG. 3 is a perspective view illustrating a representative configuration of a non-volatile memory device 100 according to embodiments, and FIG. 4 is a plan view of the non-volatile memory device 100 of FIG. 3. FIG. 5 is a cross-sectional view taken along line A-A′ of FIG. 4, and FIG. 6 is a cross-sectional view taken along line B-B′ of FIG. 4. FIG. 7 is an enlarged view of an area EX1 of FIG. 6.

Referring to FIGS. 3 to 8, the non-volatile memory device 100 includes a cell array structure CS and a peripheral circuit structure PS that overlap each other in a vertical direction Z. The cell array structure CS may include the memory cell array 20 described with reference to FIG. 1, and the peripheral circuit structure PS may include the peripheral circuit 30 described with reference to FIG. 1.

The cell array structure CS may include a plurality of memory cell blocks BLK1, BLK2 . . . BLKn. Each of the plurality of memory cell blocks BLK1, BLK2 . . . BLKn may include three-dimensionally arranged memory cells.

The peripheral circuit structure PS may include a peripheral circuit transistor 60TR and a peripheral circuit wiring structure 70 disposed on a substrate 50. The substrate 50 may include a horizontally arranged memory cell region MCR, a connection region CON, and a peripheral circuit connection region PRC. Active regions AC may be defined on the substrate 50 by the device isolation layer 52, and a plurality of peripheral circuit transistors 60TR may be formed on the active region AC. The plurality of peripheral circuit transistors 60TR may include a peripheral circuit gate 60G and a source/drain region 62 disposed on a portion of the substrate 50 on both sides of the peripheral circuit gate 60G.

The substrate 50 may include a semiconductor material, for example, a Group IV semiconductor, a Group III-V compound semiconductor, or a Group II-VI oxide semiconductor. For example, the Group IV semiconductor may include silicon (Si), germanium (Ge), or silicon-germanium. The substrate 50 may be provided as a bulk wafer or an epitaxial layer. In another embodiment, the substrate 50 may include a silicon-on-insulator (SOI) substrate or a germanium-on-insulator (GeOI) substrate. In some embodiments, the substrate 50 may include monocrystalline silicon.

The peripheral circuit wiring structure 70 includes a plurality of peripheral circuit contacts 72 and a plurality of peripheral circuit wiring layers 74. An interlayer insulating layer 80 covering the peripheral circuit transistor 60TR and the peripheral circuit wiring structure 70 may be disposed on the substrate 50. The plurality of peripheral circuit wiring layers 74 may have a multilayer structure including a plurality of metal layers disposed at different vertical levels.

A common source plate 110 may be disposed on the interlayer insulating layer 80. In some embodiments, the common source plate 110 may function as a source region supplying a current to vertical memory cells formed in the cell array structure CS. The common source plate 110 may be disposed on the memory cell region MCR, the connection region CON, and the peripheral circuit connection region PRC of the substrate 50.

In some embodiments, the common source plate 110 may include at least one of silicon (Si), germanium (Ge), silicon germanium (SiGe), gallium arsenide (GaAs), indium gallium arsenide (InGaAs), aluminum gallium arsenide (AlGaAs), or one of mixtures thereof. Also, the common source plate 110 may include a semiconductor doped with an n-type impurity. Also, the common source plate 110 may have a crystal structure including at least one selected from single crystal, amorphous, and polycrystalline. In some examples, the common source plate 110 may include polysilicon doped with an n-type impurity.

The common source plate 110 may include an opening 110H in the connection region CON and the peripheral circuit connection region PRC of the substrate 50, and an insulating plug 120 may fill an opening 110H of the common source plate 110. The insulating plug 120 may have an upper surface disposed at the same level as an upper surface of the common source plate 110.

A mold structure ST in which a plurality of gate electrodes 130 and a plurality of mold insulating layers 132 are alternately arranged in the vertical direction (the Z direction) may be located on the common source plate 110 in the memory cell region MCR and the connection region CON.

As shown in FIG. 7 as an example, the gate electrode 130 may include a buried conductive layer 130A and a conductive barrier layer 130B surrounding upper, lower (i.e., bottom), and side surfaces of the buried conductive layer 130A. For example, the buried conductive layer 130A may include a metal, such as tungsten, nickel, cobalt, or tantalum, a metal silicide, such as tungsten silicide, nickel silicide, cobalt silicide, tantalum silicide, doped polysilicon, or a combination thereof. In some embodiments, the conductive barrier layer 130B may include titanium nitride, tantalum nitride, tungsten nitride, or a combination thereof.

In some embodiments, the plurality of gate electrodes 130 may correspond to the ground select lines GSL, and word lines WL (WL1, WL2 . . . WLn-1, WLn), and at least one string select line SSL that constitute the memory cell string MS (see FIG. 2). For example, the lowermost gate electrode 130 functions as a ground select line GSL, the uppermost two gate electrodes 130 function as a string select line SSL, and the remaining gate electrodes 130 function as word lines WL (WL1, WL2 . . . WLn-1, WLn). Accordingly, a memory cell string MS in which the ground select transistor GST, the string select transistor SST, and the memory cell transistors MC1, MC2 . . . MCn-1, MCn therebetween are connected in series may be provided. In some embodiments, at least one of the gate electrodes 130 may function as a dummy word line but is not limited thereto.

As shown in FIG. 4 as an example, a plurality of gate stack separation openings WLH may extend in a first horizontal direction (X direction) parallel to the upper surface of the common source plate 110 on the common source plate 110. The plurality of gate electrodes 130 between the pair of gate stack separation openings WLH may constitute one block. For example, a first block BLK1 and a second block BLK2 are illustrated in FIG. 4.

A gate stack separation insulating layer WL1 filling the inside of the gate stack separation openings WLH may be disposed on the common source plate 110. The gate stack separation insulating layer WL1 may include a silicon oxide layer, a silicon nitride layer, SiON, SiOCN, SiCN, or a combination thereof.

A plurality of channel structures 140 may extend in a vertical direction (Z direction) passing through the plurality of gate electrodes 130 and the plurality of mold insulating layers 132 on the memory cell region MCR. The plurality of channel structures 140 may be apart from each other at predetermined intervals in the first horizontal direction (X direction), the second horizontal direction (Y direction), and the third horizontal direction (e.g., diagonal direction). The plurality of channel structures 140 may be arranged in a zigzag shape or staggered shape.

Each of the plurality of channel structures 140 may be disposed in a channel hole 140H on the memory cell region MCR. Each of the plurality of channel structures 140 may include a gate insulating layer 142, a channel layer 144, a buried insulating layer 146, and a conductive plug 148. The gate insulating layer 142 and the channel layer 144 may be sequentially disposed on a sidewall of the channel hole 140H. For example, the gate insulating layer 142 may be conformally disposed on the sidewall of the channel hole 140H, and the channel layer 144 may be conformally disposed on the sidewall and a bottom of the channel hole 140H. The buried insulating layer 146 filling a remaining space of the channel hole 140H may be disposed on the channel layer 144. A conductive plug 148 that contacts the channel layer 144 and blocks an entrance of the channel hole 140H may be disposed in an upper portion of the channel hole 140H. In other embodiments, the buried insulating layer 146 may be omitted, and the channel layer 144 may be formed in a pillar shape to fill the remaining portion of the channel hole 140H.

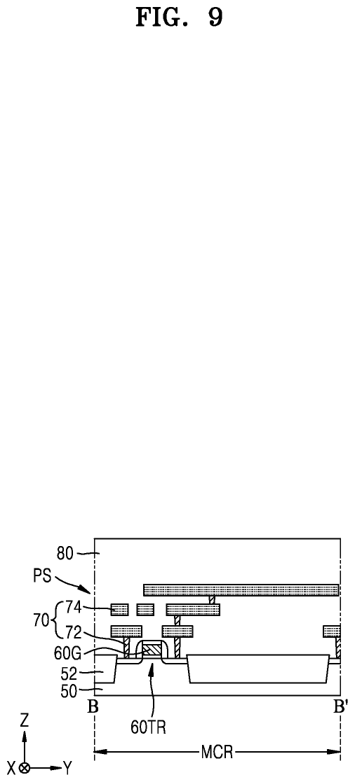

As shown in FIG. 7 as an example, the gate insulating layer 142 may have a structure in which a tunneling dielectric layer 142A, a charge storage layer 142B, and a blocking dielectric layer 142C are sequentially included on an outer wall of the channel layer 144. Relative thicknesses of the tunneling dielectric layer 142A, the charge storage layer 142B, and the blocking dielectric layer 142C constituting the gate insulating layer 142 are not limited to those illustrated in FIG. 9 and may be variously modified.

The tunneling dielectric layer 142A may include silicon oxide, hafnium oxide, aluminum oxide, zirconium oxide, tantalum oxide, or the like. The charge storage layer 142B is a region in which electrons passing through the tunneling dielectric layer 142A from the channel layer 144 may be stored. and may include silicon nitride, boron nitride, silicon boron nitride, or polysilicon doped with an impurity. The blocking dielectric layer 142C may include silicon oxide, silicon nitride, or a metal oxide having a higher permittivity than silicon oxide. The metal oxide may include hafnium oxide, aluminum oxide, zirconium oxide, tantalum oxide, or a combination thereof.

In some embodiments, a source layer 102 and a source support layer 104 may be sequentially formed on a cell substrate 101. The source layer 102 and the source support layer 104 may be disposed between the cell substrate 101 and the mold structure ST. For example, the source layer 102 and the source support layer 104 may extend along an upper surface of the cell substrate 101.

In some embodiments, the cell substrate 101 may include a semiconductor substrate, such as a silicon substrate, a germanium substrate, or a silicon-germanium substrate. Alternatively, the cell substrate 101 may include a silicon-on-insulator (SOI) substrate, a germanium-on-insulator (GOI) substrate, or the like. In some embodiments, the cell substrate 101 may include impurities. For example, the cell substrate 101 may include n-type impurities (e.g., phosphorus (P), arsenic (As), etc.). In some embodiments, the cell substrate 101 may include monocrystalline silicon.

In some embodiments, the source layer 102 may be formed to be connected to the channel layer 144 of the channel structure 140. For example, as shown in FIG. 7, the source layer 102 may pass through the gate insulating layer 142 and contact the channel layer 144. The source layer 102 may be provided as a common source line (e.g., the common source line CSL of FIG. 2) of a non-volatile memory device. In some embodiments, the source layer 102 may include, for example, doped polycrystalline silicon. In some embodiments, the source layer 102 may include metal.

In some embodiments, the channel layer 144 may be apart from the cell substrate 101 while being connected to the source layer 102. Specifically, the channel layer 144 may be apart from the cell substrate 101 with the source layer 102 therebetween.

In some embodiments, the channel structure 140 may pass through the source layer 102 and the source support layer 104. For example, a lower portion of the channel structure 140 may pass through the source layer 102 and the source support layer 104 and be buried in the cell substrate 101.

Although not shown in the drawings, a base insulating layer may be disposed between the cell substrate 101 and the source layer 102. The base insulating layer may include, for example, at least one of silicon oxide, silicon nitride, and silicon oxynitride but is not limited thereto.

In some embodiments, a lower surface of the channel layer 144 may be at a lower vertical level than an upper surface of the cell substrate 101 but is not limited thereto.

In some embodiments, a dielectric liner 149 may be disposed between the channel structure 140 and the gate electrode 130. For example, the dielectric liner 149 may be disposed between the channel structure 140 and the gate electrode 130 and on upper and lower surfaces of the gate electrode 130. For example, the dielectric liner 149 may be disposed between the gate electrode 130 and the mold insulating layer 132. In some embodiments, the dielectric liner 149 may include silicon oxide, silicon nitride, or a metal oxide having a higher permittivity than silicon oxide. The metal oxide may include hafnium oxide, aluminum oxide, zirconium oxide, tantalum oxide, or a combination thereof.

In one block BLK1 or BLK2, the uppermost two gate electrodes 130 may be separated into two portions in a plan view by a string isolation opening SSLH. A string isolation insulating layer SSLI may be disposed in the string isolation opening SSLH, and the two portions may be apart from each other in the second horizontal direction (Y direction) with the string isolation insulating layer SSLI therebetween. The two portions may configure the string select line SSL described with reference to FIG. 2.

On the connection region CON, the plurality of gate electrodes 130 may form a pad structure PAD. In the connection region CON, the plurality of gate electrodes 130 may extend to have shorter lengths in the first horizontal direction (X direction) as they move away from the upper surface of the common source plate 110. The pad structure PAD may refer to portions of the gate electrode 130 disposed in a step shape. The pad structure PAD may include a plurality of pad portions 130P extending respectively from the gate electrodes 130.

A cover insulating layer 134 may be disposed on the pad structure PAD, and a first upper insulating layer 136 may be disposed on the uppermost mold insulating layer 132 and the cover insulating layer 134.

The cell contact 160 penetrating the first upper insulating layer 136, the cover insulating layer 134, the plurality of gate electrodes 130, and the plurality of mold insulating layers 132 is disposed on the connection region CON. The cell contact 160 may be disposed inside the hole 160H penetrating the first upper insulating layer 136, the cover insulating layer 134, the plurality of gate electrodes 130, the plurality of mold insulating layers 132, and the insulating plug 120.

The cell contact 160 may include a metal, such as tungsten, nickel, cobalt, or tantalum, a metal silicide, such as tungsten silicide, nickel silicide, cobalt silicide, or tantalum silicide, doped polysilicon, or combinations thereof.

The cell contact 160 may be electrically connected to a corresponding one gate electrode 130 and may be located to be apart from at least one gate electrode 130 located at a vertical level lower than the one gate electrode 130 among the gate electrodes 130.

A bottom portion of the cell contact 160 may be surrounded by a first conductive landing via 90, and the first conductive landing via 90 may be covered by the interlayer insulating layer 80. A bottom surface of the first conductive landing via 90 may contact an upper surface of the peripheral circuit wiring layer 74. The first conductive landing via 90 may include polysilicon doped with an n-type impurity.

A through hole 180H passing through the insulating plug 120, the cover insulating layer 134, and the first upper insulating layer 136 may be disposed on the peripheral circuit connection region PRC, and a conductive through via 180 may be disposed within the through hole 180H. For example, the conductive through via 180 may include tungsten, titanium, tantalum, copper, aluminum, titanium nitride, tantalum nitride, tungsten nitride, or a combination thereof.

A second conductive landing via 92 may surround a lower sidewall of the conductive through via 180 and may be covered by the interlayer insulating layer 80. A bottom surface of the second conductive landing via 92 may contact an upper surface of the peripheral circuit wiring layer 74. The second conductive landing via 92 may include polysilicon doped with an n-type impurity.

As an example, FIG. 5 shows that the second conductive landing via 92 surrounds the lower sidewall of the conductive through via 180 and a bottom surface of the conductive through via 180 contacts the upper surface of the peripheral circuit wiring layer 74. However, unlike this, the bottom surface of the conductive through via 180 may be in contact with an upper surface of the second conductive landing via 92, and a bottom surface of the second conductive landing via 92 may be in contact with upper surface of the peripheral circuit wiring layer 74.

The cell contact 160 may be configured to be connected to the peripheral circuit transistor 60TR through the first conductive landing via 90 and the peripheral circuit wiring layer 74, and the conductive through via 180 may be configured to be connected to the peripheral circuit transistor 60TR through the second conductive landing via 92 and the peripheral circuit wiring layer 74.

On the memory cell region MCR, a bit line contact BLC may contact the conductive plug 148 of the channel structure 140 through the first upper insulating layer 136, and the bit line BL may be disposed on the bit line contact BLC. A second upper insulating layer 138 covering sidewalls of the bit lines BL may be disposed on the first upper insulating layer 136. A wiring line MLI may be disposed on the conductive through via 180 in the peripheral circuit connection region PRC.

Referring to FIG. 7 in detail, the channel layer 144 may include a plurality of channel grains 144G and a plurality of channel grain boundaries 144B that are boundaries between the plurality of channel grains 144G. In some embodiments, the channel layer 144 may include polysilicon. For example, the channel layer 144 may include a silicon channel layer. In some embodiments, each of the channel grains 144G may include a silicon grain. In some embodiments, each of the channel grain boundaries 144B may include a silicon grain boundary.

In some embodiments, the size of each of the channel grains 144G may be greater than or equal to about 20 nm. Specifically, the size of each of the channel grains 144G may be about 30 nm to about 40 nm. In some embodiments, the size of each of the channel grains 144G may be about 17 μm or less. That is, the non-volatile memory device 100 having the channel grain 144G having a size of about 20 nm or more and about 17 μm or less may be provided by embodiments without departing from the scope of the present disclosure.

In some embodiments, the size of the channel grain 144G of the channel layer 144 may be defined as follows. First, the area of a grain is measured from a cross-section passing through the channel layer 144. For example, the area of a grain is measured from a cross-section taken perpendicular to the substrate 50 and passing through the channel layer 144. Next, a circle having the same area as the calculated grain area is assumed, and the radius of the circle is calculated. The radius may be defined as the size of the channel grain 144G.

According to some embodiments, the channel layer 144 having an increased size of the channel grain 144G may be provided. When the size of the channel grain 144G increases, the current lost through the channel grain boundary 144B decreases, thereby improving channel mobility and improving cell current. When the size of the channel grain 144G increases, the distribution of the threshold voltage may be improved.

In some embodiments, as the size of the channel grain 144G increases, there may be a plurality of gate electrodes 130 overlapping one channel grain 144G in a horizontal direction (e.g., the second horizontal direction (Y direction)). Similarly, there may be a plurality of mold insulating layers 132 overlapping one channel grain 144G in a horizontal direction (e.g., the second horizontal direction (Y direction)). In some embodiments, one channel grain 144G may overlap the plurality of gate electrodes 130 and/or the plurality of mold insulating layers 132 in the second horizontal direction (Y direction). Although not shown in the drawings, one channel crystal grain 144G may overlap the plurality of gate electrodes 130 and/or the plurality of mold insulating layers 132 in the first horizontal direction (X direction).

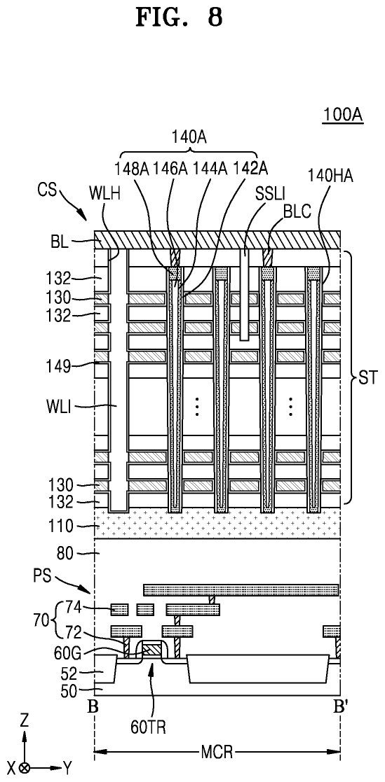

FIG. 8 illustrates a non-volatile memory device 100A according to embodiments, and is a cross-sectional view corresponding to a cross-section taken along line B-B′ of FIG. 4. Differences from the non-volatile memory device 100 described with reference to FIGS. 6 and 7 will be mainly described.

Referring to FIG. 8, the non-volatile memory device 100A may include a channel structure 140A. The channel structure 140A may extend in a vertical direction (Z direction) from an upper surface of a common source plate 110 on a memory cell region MCR, through a plurality of gate electrodes 130 and a plurality of mold insulating layers 132.

In some embodiments, a lower surface of a channel layer 144A may be disposed to contact the upper surface of the common source plate 110. In some embodiments, the channel layer 144A may not pass through the common source plate 110. In some embodiments, as shown in FIG. 8, the lower surface of the channel layer 144A may be at a lower vertical level than the upper surface of the common source plate 110 but is not limited thereto. In some embodiments, the common source plate 110 may contact an interlayer insulating layer 80. In some embodiments, the channel layer 144A may be apart from a substrate 50 with the common source plate 110 therebetween.

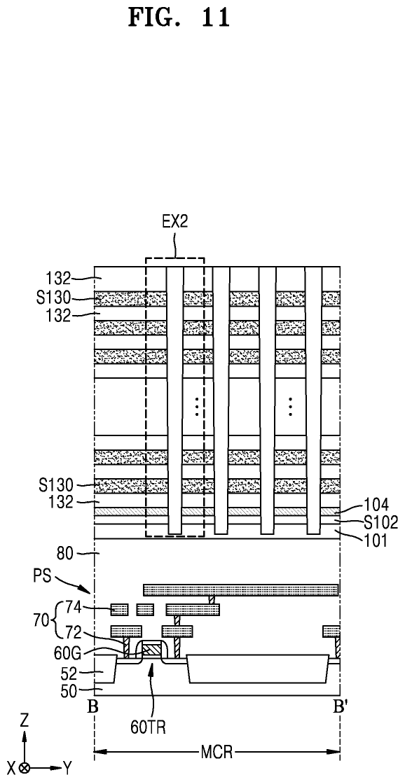

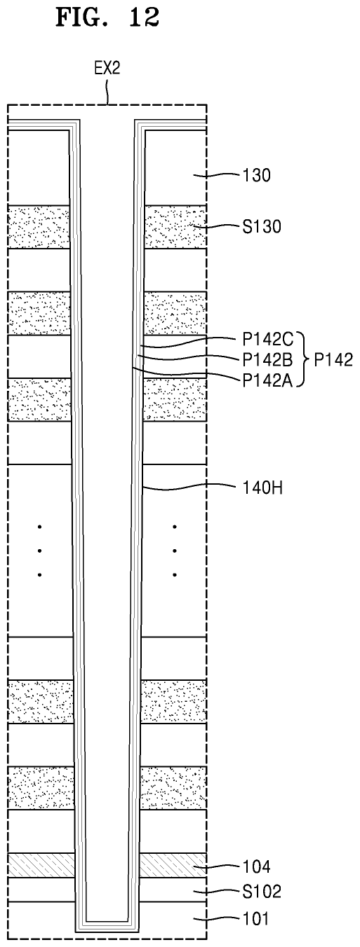

FIGS. 9 to 19 are cross-sectional views illustrating a method of manufacturing a non-volatile memory device, according to embodiments. Specifically, FIGS. 9 to 11 and FIGS. 16 to 19 are cross-sectional views corresponding to a cross-section taken along line B-B′ of FIG. 4, and FIGS. 12 to 15 are enlarged cross-sectional views corresponding to an area EX2 of FIG. 11.

Referring to FIG. 9, a peripheral circuit structure PS may be formed on a substrate 50. In example embodiments, the substrate 50 may be a monocrystalline silicon substrate. A plurality of peripheral circuit transistors 60TR may be formed on the substrate 50, and a peripheral circuit wiring structure 70 electrically connected to the peripheral circuit transistors 60TR and an interlayer insulating layer 80 may be formed.

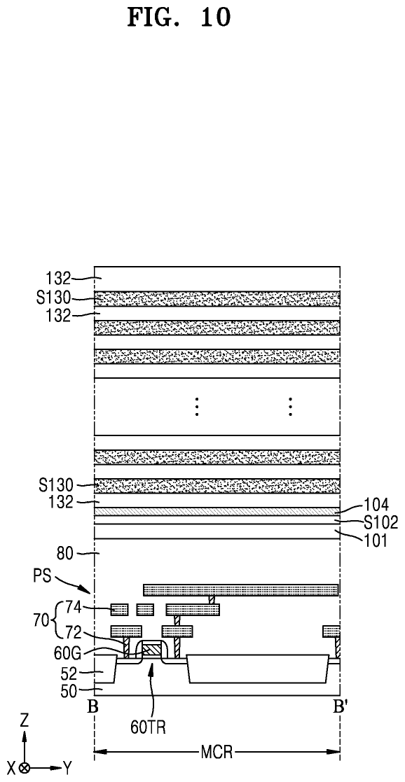

Referring to FIG. 10, a cell substrate 101, a second sacrificial layer S102, and a source support layer 104 may be sequentially formed on the interlayer insulating layer 80.

Thereafter, a plurality of mold insulating layers 132 and a plurality of first sacrificial layers S130 may be alternately formed on the second sacrificial layer S102 and the source support layer 104. In example embodiments, the plurality of mold insulating layers 132 may include an insulating material. such as silicon oxide or silicon oxynitride, and the plurality of first sacrificial layers $130 may include silicon nitride, silicon oxynitride, or polysilicon doped with an impurity.

Although not shown in the drawings, a preliminary pad structure may be formed by sequentially patterning the plurality of mold insulating layers 132 and the plurality of first sacrificial layers S130 on the connection region CON (see FIG. 5).

Referring to FIG. 11, a mask pattern (not shown) is formed on the uppermost mold insulating layer 132 and the cover insulating layer 134, and a channel hole 140H may be formed by patterning the plurality of mold insulating layers 132 and the plurality of first sacrificial layers S130 using the mask pattern as an etching mask. Specifically, the channel hole 140H may pass through the plurality of mold insulating layers 132 and the plurality of first sacrificial layers S130.

In some embodiments, the channel hole 140H may further pass through the second sacrificial layer S102 and the source support layer 104. In some embodiments, the channel hole 140H may be formed by patterning an upper portion of the cell substrate 101. Specifically, in some embodiments, the channel hole 140H may not pass through the cell substrate 101.

Hereinafter, a method of forming a channel structure 140 in the channel hole 140H will be described with reference to FIGS. 12 to 16.

Referring to FIG. 12, a pre-gate insulating layer P142 may be formed in the channel hole 140H. Specifically, a pre-blocking dielectric layer P142C, a pre-charge storage layer P142B, and a pre-tunneling dielectric layer P142A conformally covering a lower surface and sidewall of the channel hole 140H may be sequentially formed. In some embodiments, the pre-gate insulating layer P142 may also be formed on the uppermost mold insulating layer 132.

In some embodiments, the pre-gate insulating layer P142 may contact the cell substrate 101, the second sacrificial layer S102, and the source support layer 104 on the lower surface of the channel hole 140H and on the sidewall adjacent to the lower surface. Specifically, the pre-gate insulating layer P142 may contact the cell substrate 101, the second sacrificial layer S102, and the source support layer 104, which are exposed through the channel hole 140H.

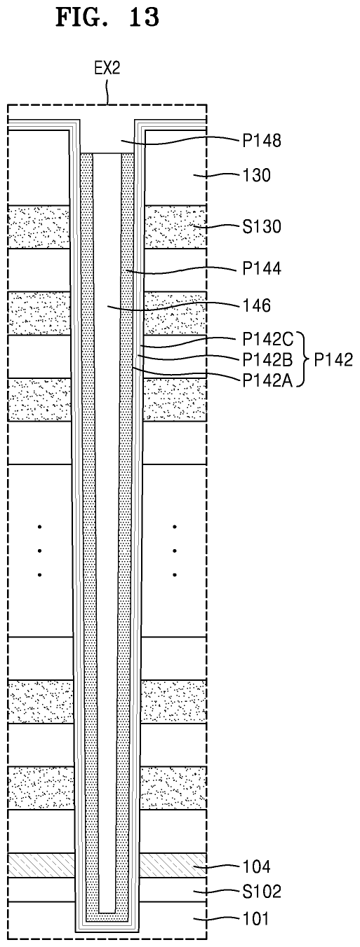

Referring to FIG. 13, a pre-channel layer P144 may be formed on the pre-gate insulating layer P142. The pre-channel layer P144 may conformally cover the pre-gate insulating layer P142 on the lower surface and sidewall of the channel hole 140H. In some embodiments, the pre-channel layer P144 may include amorphous silicon. In some embodiments, the pre-channel layer P144 may not contact the cell substrate 101. Specifically, the pre-channel layer P144 may be apart from the cell substrate 101 with the pre-gate insulating layer P142 therebetween.

Subsequently, a buried insulating layer 146 and a pre-conductive plug P148 may be formed on the pre-channel layer P144. The pre-conductive plug P148 may fill an upper end of the channel hole 140H while contacting upper portions of the pre-channel layer P144 and the buried insulating layer 146. In some embodiments, the pre-conductive plug P148 may also be formed on the uppermost mold insulating layer 132.

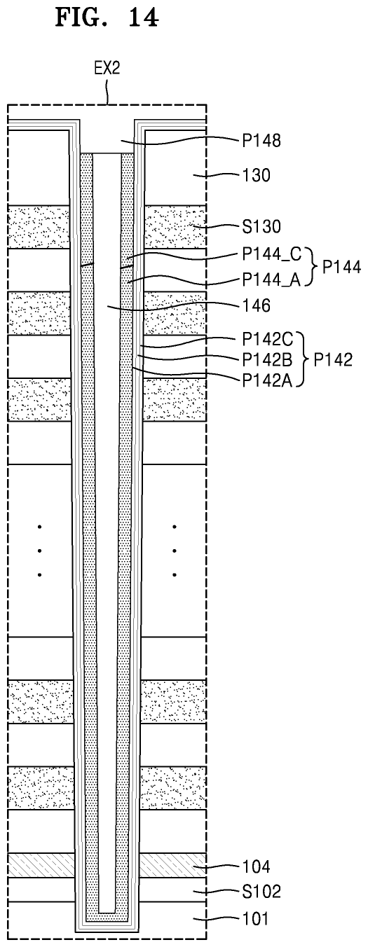

Referring to FIG. 14, an upper portion of the pre-channel layer P144 may be first crystallized to form a channel layer crystal P144_C. Specifically, the channel layer crystal P144_C may be formed by crystallizing only the upper portion of the pre-channel layer P144. That is, at least a portion of the pre-channel layer P144, e.g., a lower portion, may not be crystallized. In some embodiments, the channel layer crystal P144_C may include a single crystal. Specifically, when the pre-channel layer P144 includes amorphous silicon, the channel layer crystal P144_C may include single-crystal silicon.

In some embodiments, a process of forming the channel layer crystal P144_C by crystallizing an upper portion of the pre-channel layer P144 may use a laser. Specifically, the upper portion of the pre-channel layer P144 may be crystallized by irradiating a laser beam toward the upper portion. For example, crystallization may be performed by applying heat to only the upper portion of the pre-channel layer P144 by using a laser. That is, energy required for crystallization may be supplied only to a local area, for example, an upper portion of the pre-channel layer P144 by using a laser.

In some other embodiments, the process of forming the channel layer crystal P144_C by crystallizing the upper portion of the pre-channel layer P144 may use a heat source other than a laser to supply energy required for crystallization to only a local area, for example, the upper portion of the pre-channel layer P144.

Through the above process, a lower portion of the pre-channel layer P144 may remain in an amorphous state. Specifically, a portion of the pre-channel layer P144 excluding the channel layer crystal P144_C may include an amorphous channel layer P144_A. Specifically, when the pre-channel layer P144 includes amorphous silicon, the amorphous channel layer P144_A may include amorphous silicon.

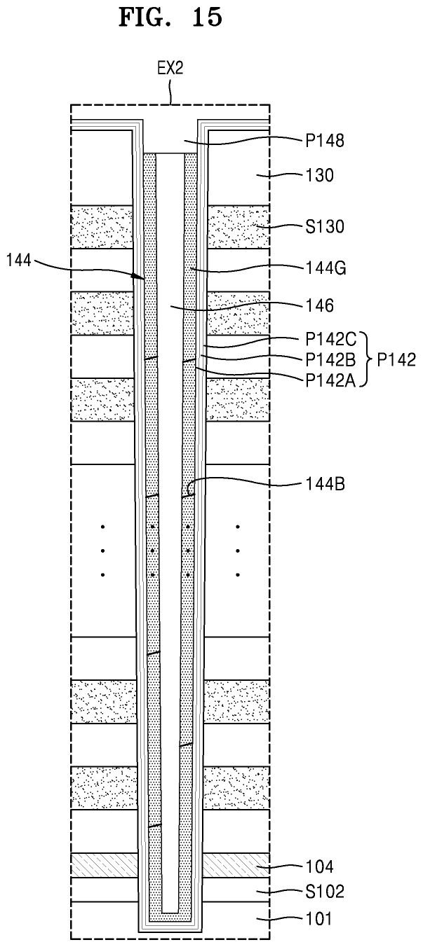

Referring to FIG. 15, a channel layer 144 may be formed by performing solid phase epitaxy (SPE). Specifically, the channel layer 144 including polycrystalline may be formed by performing SPE on the amorphous channel layer P144_A by using the channel layer crystal P144_C as a seed layer.

In some embodiments, when an already crystallized channel layer crystal P144_C is used as the seed layer, SPE may be performed along the orientation of the channel layer crystal P144_C as the seed layer. When SPE is performed along the orientation of the channel layer crystal P144_C as the seed layer, a channel grain 144G having a large size may be generated. Specifically, the channel grain 144G having a size of about 20 nm or more and about 17 μm or less may be generated. Specifically, grains having a size of about 30 nm to about 40 nm may be generated.

In some embodiments, the process of forming the channel layer 144 by performing the SPE may be performed in a temperature range lower than a temperature at which random nucleation and growth (RNG) may occur. For example, the process of forming the channel layer 144 by performing the SPE may be performed at a temperature of about 500° C. to about 600° C. That is, in some embodiments, RNG may not be performed while performing the SPE.

In some embodiments, when the channel layer 144 is formed through an SPE process, the size of grains may increase compared to when the channel layer 144 is formed through RNG. For example, in a comparative example, a channel layer having grains of less than 10 nm may be formed by RNG. For example, in a comparative example, grains of about 20 nm or more may not be formed by RNG. In alternative embodiments, when the channel layer 144 is formed through an SPE process, grains of about 20 nm or more may be formed, and thus, the size of grains may increase compared to the case by RNG.

In some embodiments, as described above, the pre-channel layer P144 may be apart from the cell substrate 101 with the pre-gate insulating layer P142 therebetween, and thus, the cell substrate 101 may not be used as a seed layer in the process of crystallizing the pre-channel layer P144 to form the channel layer 144.

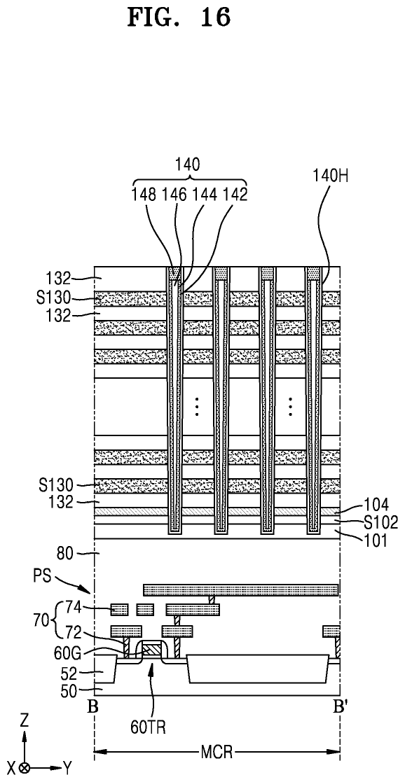

Referring to FIG. 16, a channel structure 140 may be formed by removing portions of the pre-gate insulating layer P142 and the pre-conductive plug P148 on the uppermost mold insulating layer 132. Specifically, a gate insulating layer 142 may be formed by removing a portion of the pre-gate insulating layer P142 on the uppermost mold insulating layer 132. Specifically, a conductive plug 148 may be formed by removing a portion of the pre-conductive plug P148 on the uppermost mold insulating layer 132. The process of removing a portion of the pre-gate insulating layer P142 and the process of removing a portion of the pre-conductive plug P148 may be simultaneously performed.

Although not shown in the drawings, in the process of forming the channel structure 140 described with reference to FIGS. 12 to 16, a dummy channel structure passing through a preliminary pad structure may also be formed in the connection region CON (see FIG. 5).

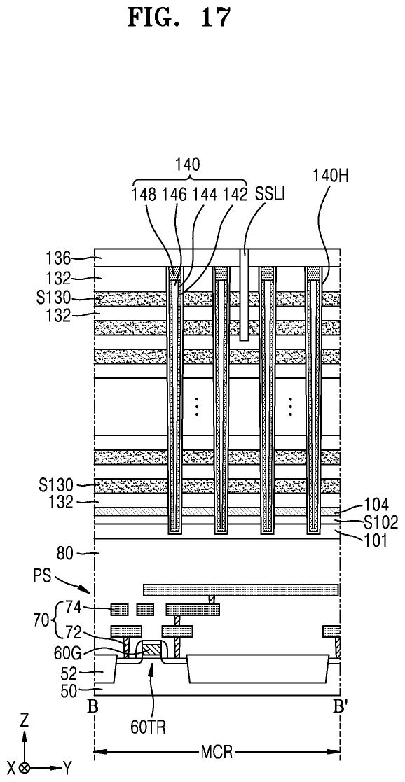

Referring to FIG. 17, a first upper insulating layer 136 covering the uppermost mold insulating layer 132, the cover insulating layer 134, and the channel structure 140 may be formed.

On the memory cell region MCR, the first upper insulating layer 136, the uppermost two first sacrificial layers S130, and the uppermost two mold insulating layers 132 may be removed to form a string separation opening SSLH, and a string separation insulating layer SSLI filling the string separation opening SSLH may be formed by using an insulating material.

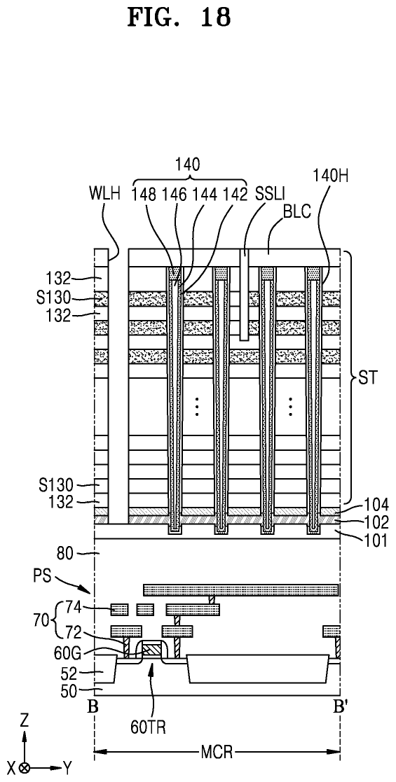

Referring to FIG. 18, a mask pattern (not shown) may be formed on the first upper insulating layer 136, and portions of the plurality of mold insulating layers 132 and the plurality of first sacrificial layers S130 may be removed using the mask pattern as an etch mask to form a gate stack separation opening WLH. The plurality of first sacrificial layers S130 may be exposed on an inner wall of the gate stack separation opening WLH.

In the process of forming the gate stack separation opening WLH, portions of the second sacrificial layer S102 (see FIG. 17) and the source support layer 104 may be removed together. The second sacrificial layer S102 and the source support layer 104 may be exposed on the inner wall of the gate stack separation opening WLH.

Subsequently, the second sacrificial layer S102 exposed through the gate stack separation opening WLH may be removed. The source support layer 104 may be used as a support layer to prevent a mold stack from collapsing in the process of removing the second sacrificial layer S102. In some embodiments, a side surface of the gate insulating layer 142 may be exposed by removing the second sacrificial layer S102.

Subsequently, a portion of the gate insulating layer 142 exposed by removing the second sacrificial layer S102 may be removed. Specifically, before the second sacrificial layer S102 is removed, a portion of the gate insulating layer 142 overlapping the second sacrificial layer S102 in the second horizontal direction (Y direction) may be removed. In some embodiments, a portion of the gate insulating layer 142 that does not overlap the second sacrificial layer S102 in the second horizontal direction (Y direction) may also be removed. Accordingly, a portion of the outer wall of the channel layer 144 may be exposed. As a result, portions of the second sacrificial layer S102 and the gate insulating layer 142 may be removed to form a T-shaped recess.

Subsequently, a source layer 102 may be formed by filling the T-shaped recess formed by removing the portions of the second sacrificial layer S102 and the gate insulating layer 142. That is, the source layer 102 in contact with the channel layer 144 may be formed. For example, the source layer 102 in contact with the outer wall of the channel layer 144 may be formed.

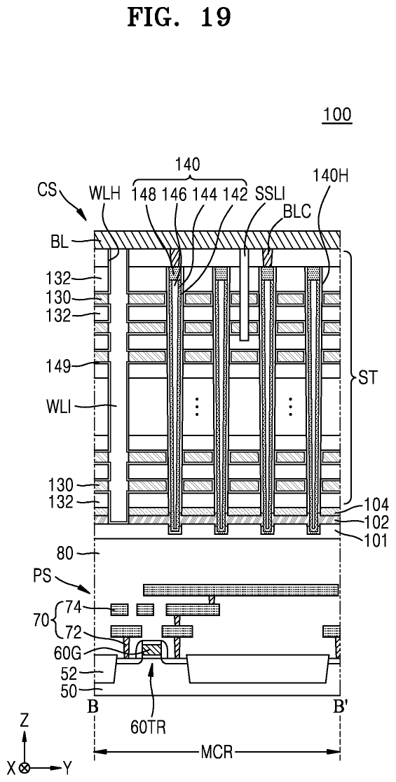

Referring to FIG. 19, a gate electrode 130 may be formed by removing the first sacrificial layer S130 and filling a conductive material in the empty portion.

Subsequently, an insulating material may be filled in the gate stack separation opening WLH to form a gate stack separation insulating layer WL1. Thereafter, a bit line contact BLC electrically connected to the channel structure 140 through the first upper insulating layer 136 may be formed. Thereafter, a bit line BL electrically connected to the bit line contact BLC may be formed on the memory cell region MCR.

The manufacture of the memory device 100 may be completed by performing the processes described above.

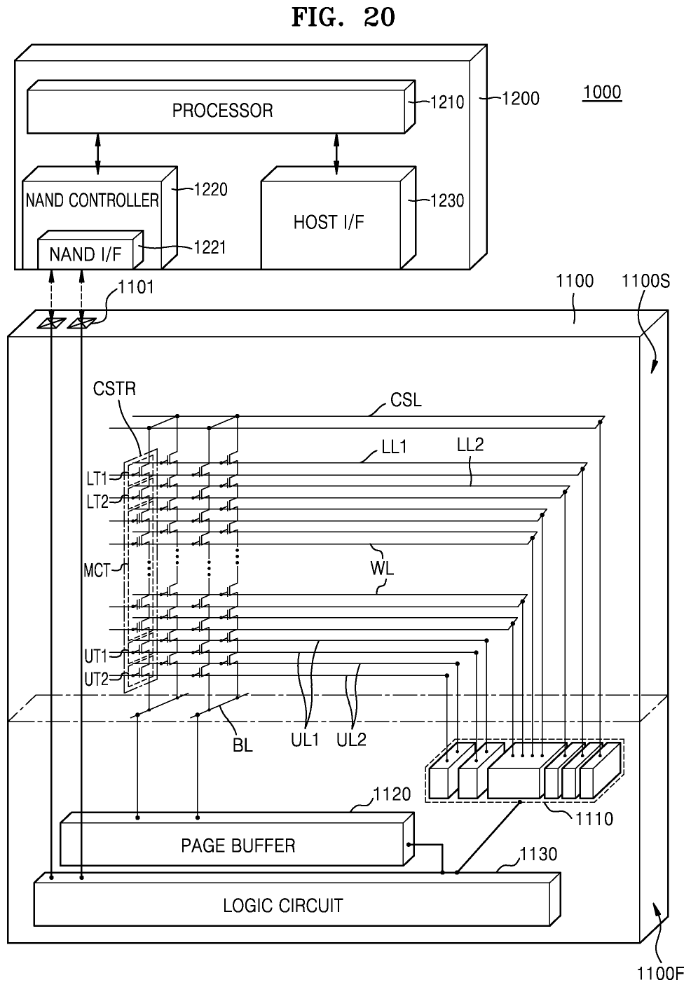

FIG. 20 is a schematic diagram illustrating a data storage system 1000 including a non-volatile memory device according to embodiments.

Referring to FIG. 20, the data storage system 1000 may include one or more non-volatile memory devices 1100 and a memory controller 1200 electrically connected to the non-volatile memory device 1100. The data storage system 1000 may be, for example, a solid-state drive (SSD) device, a Universal Serial Bus (USB), a computing system, a medical device, or a communication device including at least one non-volatile memory device 1100.

For example, the non-volatile memory device 1100 may be a NAND flash non-volatile memory device including one of the non-volatile memory devices 100 and 100A described with reference to FIGS. 1 to 8. The non-volatile memory device 1100 may include a first structure 1100F and a second structure 1100S on the first structure 1100F. The first structure 1100F may be a peripheral circuit structure including a row decoder 1110, a page buffer 1120, and a logic circuit 1130.

The second structure 1100S includes a bit line BL, a common source line CSL, a plurality of word lines WL, first and second string select lines UL1 and UL2, first and second ground select lines LL1 and LL2, and a plurality of memory cell strings CSTR between the bit line BL and the common source line CSL.

In the second structure 1100S, the plurality of memory cell strings CSTR may include ground select transistors LT1 and LT2 adjacent to the common source line CSL, respectively, string select transistors UT1 and UT2 adjacent to the bit line BL, respectively, and a plurality of memory cell transistors MCT between the ground select transistors LT1 and LT2 and the string select transistors UT1 and UT2. The number of ground select transistors LT1 and LT2 and the number of string select transistors UT1 and UT2 may be variously modified according to embodiments.

In some embodiments, the plurality of ground select lines LL1 and LL2 may be connected to gate electrodes of the ground select transistors LT1 and LT2, respectively. The word line WL may be connected to the gate electrode of the memory cell transistor MCT. The plurality of string select lines UL1 and UL2 may be connected to gate electrodes of the string select transistors UT1 and UT2, respectively.

The common source line CSL, the plurality of ground select lines LL1 and LL2, the plurality of word lines WL, and the plurality of string select lines UL1 and UL2 may be connected to the row decoder 1110. The plurality of bit lines BL may be electrically connected to the page buffer 1120.

The non-volatile memory device 1100 may communicate with the memory controller 1200 through an input/output pad 1101 electrically connected to the logic circuit 1130. The input/output pad 1101 may be electrically connected to the logic circuit 1130.

The memory controller 1200 may include a processor 1210, a NAND controller 1220, and a host interface 1230. In some embodiments, the data storage system 1000 may include a plurality of non-volatile memory devices 1100, and in this case, the memory controller 1200 may control the plurality of non-volatile memory devices 1100.

The processor 1210 may control overall operations of the data storage system 1000 including the memory controller 1200. The processor 1210 may operate according to predetermined firmware and may access the non-volatile memory device 1100 by controlling the NAND controller 1220. The NAND controller 1220 may include a NAND interface 1221 that processes communication with the non-volatile memory device 1100. A control command for controlling the non-volatile memory device 1100. data to be written to a plurality of memory cell transistors MCT of the non-volatile memory device 1100, and data to be read from the plurality of memory cell transistors MCT of the non-volatile memory device 1100 may be transmitted through the NAND interface 1221. The host interface 1230 may provide a communication function between the data storage system 1000 and an external host. When a control command is received from an external host through the host interface 1230, the processor 1210 may control the non-volatile memory device 1100 in response to the control command.

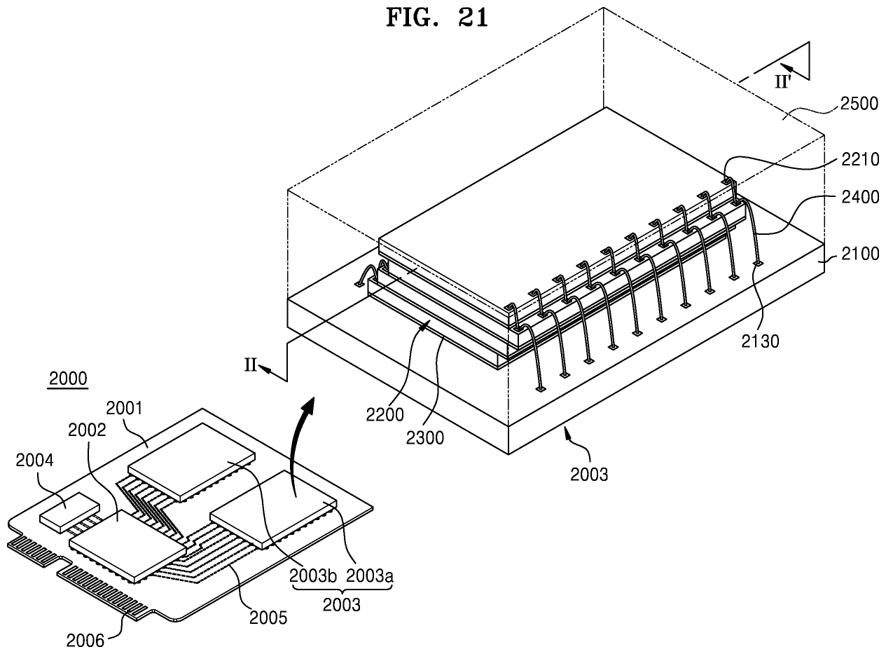

FIG. 21 is a perspective view schematically illustrating a data storage system 2000 including a non-volatile memory device according to embodiments.

Referring to FIG. 21, the data storage system 2000 according to an embodiment may include a main substrate 2001, a memory controller 2002 mounted on the main substrate 2001, one or more semiconductor packages 2003, and dynamic random-access memory (DRAM) 2004. The semiconductor package 2003 and the DRAM 2004 may be connected to the memory controller 2002 through a plurality of wiring patterns 2005 formed on the main substrate 2001.

The main substrate 2001 may include a connector 2006 including a plurality of pins coupled to an external host. The number and arrangement of the plurality of pins in the connector 2006 may vary depending on the communication interface between the data storage system 2000 and the external host. In some embodiments, the data storage system 2000 may communicate with an external host according to any one of interfaces, such as USB, Peripheral Component Interconnect Express (PCI-Express), Serial Advanced Technology Attachment (SATA), M-Phy for Universal Flash Storage (UFS), etc. In some embodiments, the data storage system 2000 may be operated by power supplied from an external host through the connector 2006. The data storage system 2000 may further include a power management integrated circuit (PMIC) that distributes power supplied from the external host to the memory controller 2002 and the semiconductor package 2003.

The memory controller 2002 may write data to the semiconductor package 2003, may read data from the semiconductor package 2003, and may improve an operating speed of the data storage system 2000.

The DRAM 2004 may be a buffer memory for mitigating a speed difference between the semiconductor package 2003, which is a data storage space, and an external host. The DRAM 2004 included in the data storage system 2000 may also operate as a kind of cache memory, and may provide a space for temporarily storing data in a control operation for the semiconductor package 2003. When the DRAM 2004 is included in the data storage system 2000, the memory controller 2002 may further include a DRAM controller for controlling the DRAM 2004 in addition to the NAND controller for controlling the semiconductor package 2003.

The semiconductor package 2003 may include first and second semiconductor packages 2003a and 2003b separated from each other. The first and second semiconductor packages 2003a and 2003b may be semiconductor packages each including a plurality of semiconductor chips 2200. Each of the first and second semiconductor packages 2003a and 2003b may include a package substrate 2100, a plurality of semiconductor chips 2200 on the package substrate 2100, an adhesive layer 2300 disposed on a lower surface of each of the plurality of semiconductor chips 2200, a connection structure 2400 electrically connecting the plurality of semiconductor chips 2200 to the package substrate 2100, and a molding layer 2500 covering the plurality of semiconductor chips 2200 and the connection structure 2400 on the package substrate 2100.

The package substrate 2100 may be a printed circuit board including a plurality of package upper pads 2130. Each of the plurality of semiconductor chips 2200 may include an input/output pad 2210. The input/output pad 2210 may correspond to the input/output pad 1101 of FIG. 20. Each of the plurality of semiconductor chips 2200 may include at least one of the non-volatile memory devices 100 and 100A described with reference to FIGS. 1 to 8.

In some embodiments, the connection structure 2400 may be a bonding wire electrically connecting the input/output pad 2210 to a package upper pad 2130. Accordingly, in the first and second semiconductor packages 2003a and 2003b, the plurality of semiconductor chips 2200 may be electrically connected to each other using a bonding wire method and may be electrically connected to the package upper pad 2130 of the package substrate 2100. In some embodiments, in the first and second semiconductor packages 2003a and 2003b, the plurality of semiconductor chips 2200 may be electrically connected to each other by a connection structure including through silicon vias (TSVs) instead of the connection structure 2400 that uses a bonding wire method.

In some embodiments, the memory controller 2002 and the plurality of semiconductor chips 2200 may be included in one package. In some embodiment, the memory controller 2002 and the plurality of semiconductor chips 2200 are mounted on a separate interposer substrate that is different from the main substrate 2001, and the memory controller 2002 and the plurality of semiconductor chips 2200 may be connected to each other by wirings formed on the interposer substrate.

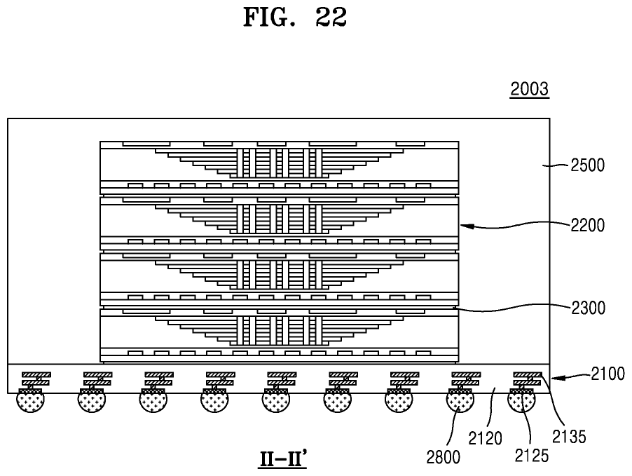

FIG. 22 is a schematic cross-sectional view illustrating semiconductor packages according to embodiments. Specifically, FIG. 22 is a cross-sectional view taken along line II-II′ of FIG. 21.

Referring to FIG. 22, in the semiconductor package 2003, the package substrate 2100 may be a printed circuit board. The package substrate 2100 may include a package substrate body unit 2120, a plurality of package upper pads 2130 (see FIG. 21) disposed on an upper surface of the package substrate body unit 2120, a plurality of lower pads 2125 disposed on a lower surface of the package substrate body 2120 or exposed through the lower surface, and a plurality of internal wirings 2135 that electrically connect the plurality of package upper pads 2130 (see FIG. 21) and the plurality of lower pads 2125 inside the package substrate body unit 2120. As shown in FIG. 21, the plurality of package upper pads 2130 may be electrically connected to the plurality of connection structures 2400. As shown in FIG. 22, the plurality of lower pads 2125 may be connected to the plurality of wiring patterns 2005 on the main substrate 2001 of the data storage system 2000 shown in FIG. 21 through a plurality of conductive bumps 2800. Each of the plurality of semiconductor chips 2200 may include at least one of the non-volatile memory devices 100 and 100A described with reference to FIGS. 1 to 8.

While various embodiments have been particularly shown and described with reference to embodiments thereof, it will be understood that various changes in form and details may be made therein without departing from the spirit and scope of the following claims.

What is claimed is:

1. A non-volatile memory device comprising:
a substrate including a memory cell region and a connection region;
a mold structure including a plurality of gate electrodes sequentially stacked on the memory cell region and stacked stepwise on the connection region, and a plurality of mold insulating layers alternately stacked with the plurality of gate electrodes;
a channel hole vertically passing through the mold structure on the memory cell region; and
a channel structure disposed in the channel hole,
wherein the channel structure includes a gate insulating layer, a channel layer, and a buried insulating layer sequentially disposed in the channel hole, and
the channel layer includes a grain having a size of about 20 nm to about 17 μm.

2. The non-volatile memory device of claim 1, wherein the channel layer includes a silicon channel layer, and a size of the grain of the silicon channel layer is about 20 nm to about 17 μm.

3. The non-volatile memory device of claim 1, wherein the grain of the channel layer overlaps the plurality of gate electrodes in a horizontal direction.

4. The non-volatile memory device of claim 1, wherein the channel layer is apart from the substrate.

5. The non-volatile memory device of claim 4, further comprising a source layer disposed between the substrate and the mold structure,
wherein the channel layer is in contact with the source layer.

6. The non-volatile memory device of claim 5, wherein the source layer passes through the gate insulating layer and contacts an outer wall of the channel layer.

7. The non-volatile memory device of claim 5, wherein the source layer is in contact with a lower surface of the channel layer.

8. The non-volatile memory device of claim 5, wherein the source layer includes doped polycrystalline silicon.

9. The non-volatile memory device of claim 4, wherein the substrate includes single-crystal silicon.

10. A non-volatile memory device comprising:
a peripheral circuit structure and a cell array structure sequentially stacked on a substrate,
wherein the cell array structure includes:
a mold structure including a plurality of gate electrodes sequentially stacked on a memory cell region of the substrate and stacked stepwise on a connection region of the substrate, and a plurality of mold insulating layers alternately stacked with the plurality of gate electrodes; and
a channel layer vertically passing through the mold structure on the memory cell region and intersecting with the plurality of gate electrodes,
wherein the channel layer includes a grain having a size of about 20 nm to about 17 μm.

11. The non-volatile memory device of claim 10, further comprising:
a gate insulating layer extending in a vertical direction between the channel layer and the mold structure; and
a buried insulating layer apart from the gate insulating layer with the channel layer therebetween.

12. The non-volatile memory device of claim 11, wherein the gate insulating layer includes a tunneling dielectric layer, a charge storage layer, and a blocking dielectric layer sequentially disposed on an outer wall of the channel layer.

13. The non-volatile memory device of claim 10, wherein the grain of the channel layer overlaps the plurality of gate electrodes in a horizontal direction.

14. The non-volatile memory device of claim 10, further comprising a source layer disposed between the substrate and the mold structure,
wherein the channel layer is apart from the substrate with the source layer therebetween.

15. The non-volatile memory device of claim 14, wherein the substrate includes single-crystal silicon, and the source layer includes doped polycrystalline silicon.

16. The non-volatile memory device of claim 14, further comprising a gate insulating layer extending in a vertical direction between the channel layer and the mold structure,
wherein the source layer passes through the gate insulating layer and contacts the channel layer.

17. The non-volatile memory device of claim 14, wherein the source layer is in contact with a lower surface of the channel layer.

18. The non-volatile memory device of claim 14, wherein the peripheral circuit structure includes a peripheral circuit transistor; a peripheral circuit wiring structure electrically connected to the peripheral circuit transistor; and an interlayer insulating layer covering the peripheral circuit wiring structure, and the interlayer insulating layer is in contact with the source layer.

19. An electronic system comprising:
a main board;
a non-volatile memory device on the main board; and
a controller electrically connected to the non-volatile memory device on the main board,
wherein the non-volatile memory device includes:
a substrate including a memory cell region and a connection region;
a mold structure including a plurality of gate electrodes sequentially stacked on the memory cell region and stacked stepwise on the connection region, and a plurality of mold insulating layers alternately stacked with the plurality of gate electrodes;
a source layer disposed between the substrate and the mold structure;
a channel hole vertically passing through the mold structure on the memory cell region; and
a channel structure disposed in the channel hole,
wherein the channel structure includes a gate insulating layer, a silicon channel layer, and a buried insulating layer sequentially disposed in the channel hole,
the silicon channel layer is apart from the substrate with the source layer therebetween, and
the silicon channel layer includes a silicon grain having a size of about 20 nm to about 17 μm.

20. The electronic system of claim 19, wherein the silicon grain of the silicon channel layer overlaps the plurality of gate electrodes in a horizontal direction.
